(19) United States
(12) Patent Application Publication
(10) Pub. No.: US 2025/0142961 A1
(43) Pub. Date: May 1, 2025

(54) ARRAY SUBSTRATE, DISPLAY PANEL, AND METHOD FOR MANUFACTURING ARRAY SUBSTRATE

(71) Applicants: Hefei Visionox Technology Co., Ltd., Hefei (CN); KunShan Go-Visionox Opto-Electronics Co., Ltd., Kunshan (CN)

(72) Inventors: Huang-Tai CHAN, Hefei (CN); Yang LI, Hefei (CN); Chao Chi PENG, Hefei (CN)

(73) Assignees: Hefei Visionox Technology Co., Ltd., Hefei (CN); KunShan Go-Visionox Opto-Electronics Co., Ltd., Kunshan (CN)

(21) Appl. No.: 19/008,677

(22) Filed: Jan. 3, 2025

Related U.S. Application Data
(63) Continuation of application No. PCT/CN2022/130720, filed on Nov. 8, 2022.

(30) Foreign Application Priority Data
Aug. 24, 2022 (CN) 202211023799.7

(51) Int. Cl. H10D 86/40; H10D 86/01

(52) U.S. Cl. CPC H10D 86/441; H10D 86/021; H10D 86/451

(57) ABSTRACT

The present application discloses an array substrate, a display panel, and a method for manufacturing an array substrate. The array substrate includes a substrate; a first insulating layer located on one side of the substrate, a surface of the first insulating layer facing away from the substrate being recessed to form a confining groove; a first metal layer located on a side of the first insulating layer facing away from the substrate, the first metal layer including a signal line, the signal line including a first branch and a second branch surrounding at least part of the first branch, the first branch being located in the confining groove, and at least part of the second branch being located on the surface of the first insulating layer facing away from the substrate; and a second insulating layer located on a side of the first metal layer facing away from the substrate.

### CROSS-REFERENCE TO RELATED APPLICATIONS

The present application is a continuation of International Application No. PCT/CN2022/130720 filed on Nov. 8, 2022, which claims priority to Chinese Patent Application No. 202211023799.7, entitled “ARRAY SUBSTRATE, DISPLAY PANEL, AND METHOD FOR MANUFACTURING ARRAY SUBSTRATE” and filed on Aug. 24, 2022, the entire contents of which are incorporated herein by reference.

### TECHNICAL FIELD

The present application relates to the field of display, and in particular to an array substrate, a display panel, and a method for manufacturing an array substrate.

### BACKGROUND

With the rapid development of electronic devices, users have higher and higher requirements for display panels. A display panel includes a light-emitting device and a driving device. The driving device includes components such as a thin film transistor and a capacitor plate that require two layers of wires to overlap at a specific position. Among such components, if an overlapping position of the two layers of wires is inaccurate, device characteristics may be unstable, and a yield of the display panel may be affected.

### SUMMARY

Embodiments of the present application provide an array substrate, a display panel, and a method for manufacturing an array substrate, intended to provide an array substrate with stable device characteristics.

In a first aspect of the present application, an embodiment provides an array substrate, including: a substrate; a first insulating layer located on one side of the substrate, a surface of the first insulating layer facing away from the substrate being recessed to form a confining groove; a first metal layer located on a side of the first insulating layer facing away from the substrate, the first metal layer including a signal line, the signal line including a first branch and a second branch surrounding at least part of the first branch, the first branch being located in the confining groove, and at least part of the second branch being located on the surface of the first insulating layer facing away from the substrate; and a second insulating layer located on a side of the first metal layer facing away from the substrate, the second insulating layer including an accommodating groove with an opening facing the first metal layer, and the second branch being located in the accommodating groove.

In a second aspect of the present application, an embodiment provides a display panel, including the array substrate in any one of the above implementations.

In a third aspect of the present application, an embodiment provides a method for manufacturing an array substrate, including: arranging a first insulating material layer on a substrate, and patterning the first insulating material layer to form a first insulating layer including a confining groove, a surface of the first insulating layer facing away from the substrate being recessed to form the confining groove; arranging a first metal material layer on a side of the first insulating layer facing away from the substrate, and patterning, by using a wet etching process, the first metal material layer to form a first metal layer including a signal line, the signal line including a first branch and a second branch surrounding at least part of the first branch, the first branch being located in the confining groove, and at least part of the second branch being located on the surface of the first insulating layer facing away from the substrate; and arranging an insulating material on a side of the first metal layer facing away from the first insulating layer to form a second insulating layer, at least part of the insulating material being deposited on the second branch to form an accommodating groove having an opening facing the first metal layer and accommodating the second branch.

In the array substrate provided in the embodiments of the present application, the array substrate includes the substrate, the first insulating layer, the first metal layer, and the second insulating layer. The first insulating layer is provided with the confining groove, and at least part of the signal line is located in the confining groove. The signal line includes the first branch located in the confining groove and the second branch located outside the confining groove, the accommodating groove in the second insulating layer accommodates the second branch, and the second insulating layer may be directly deposited on the first insulating layer and the first metal layer, which can simplify manufacturing of the array substrate. The confining groove can provide a limit to the signal line, thereby determining a position and dimensions of the signal line. Therefore, the signal line can be manufactured by using a more mature process such as wet etching, which can simplify manufacturing of the array substrate. In addition, when the signal line is required to overlap with another wire, a distance between the signal line in the confining groove and the another wire is relatively short. Therefore, dimensions of an overlapping region between the signal line in the confining groove and the another wire can affect device characteristics. By reasonably arranging the dimensions and the position of the confining groove, the characteristics of the device can be controlled, thereby improving the stability of device characteristics. Hence, the array substrate provided in the embodiments of the present application has the advantage of stable device characteristics.

### BRIEF DESCRIPTION OF THE DRAWINGS

Other features, objectives, and advantages of the present application will be more apparent upon reading the following detailed description of non-limiting embodiments with reference to the accompanying drawings. Same or similar reference signs indicate same or similar features, and the accompanying drawings have not necessarily been drawn to actual scale.

FIG. 1 is a partial sectional view of an array substrate according to an embodiment in a first aspect of the present application;

FIG. 2 is a partial sectional view of an array substrate according to another embodiment in the first aspect of the present application;

FIG. 3 is a partial sectional view of an array substrate according to still another embodiment in the first aspect of the present application;

FIG. 4 is a partial sectional view of an array substrate according to yet another embodiment in the first aspect of the present application;

FIG. 5 is a partial sectional view of an array substrate according to a further embodiment in the first aspect of the present application;

FIG. 6 is a partial sectional view of an array substrate according to a further embodiment in the first aspect of the present application;

FIG. 7 is a partial sectional view of an array substrate according to a further embodiment in the first aspect of the present application;

FIG. 8 is a partial sectional view of an array substrate according to a further embodiment in the first aspect of the present application;

FIG. 9 is a top view of a partial layer structure of an array substrate according to an embodiment in the first aspect of the present application;

FIG. 10 is a top view of a partial layer structure of an array substrate according to another embodiment in the first aspect of the present application;

FIG. 11 is a top view of a partial layer structure of an array substrate according to yet another embodiment in the first aspect of the present application;

FIG. 12 is a partial sectional view of a display panel according to an embodiment in a second aspect of the present application;

FIG. 13 is a schematic flowchart of a method for manufacturing an array substrate according to an embodiment in a third aspect of the present application;

FIG. 14 is a schematic flowchart of a step in a method for manufacturing an array substrate according to an embodiment in the third aspect of the present application; and

FIG. 15 is a schematic flowchart of another step in a method for manufacturing an array substrate according to an embodiment in the third aspect of the present application.

### REFERENCE SIGNS

1: display panel; 10: array substrate; 20: pixel electrode layer; 21: pixel electrode; 30: pixel defining layer; 31: isolation portion; 32: pixel opening; 40: light-emitting unit; 50: common electrode layer;
100: substrate; 110: shielding portion;
200: active layer; 210: semiconductor portion; 211: source region; 212: drain region; 213: channel region; 20: pixel electrode layer; 21: pixel electrode;
300: first insulating layer; 301: confining groove; 310: first sub-insulating layer; 320: second sub-insulating layer; 321: insulating defining portion; 330: insulating stop layer; 331: etching stop portion; 30: pixel defining layer; 31: isolation portion; 32: pixel opening; 400: first metal layer; 410: signal line; 411: first sub-layer; 412: second sub-layer; 413: first branch; 414: second branch; 414a: avoiding groove; 414b: avoiding hole; 40: light-emitting unit;
500: second metal layer; 510: source; 520: drain; 501: first sub-section; 502: second sub-section; 50: common electrode layer;
600: second insulating layer.

### DETAILED DESCRIPTION

Features and exemplary embodiments in various aspects of the present application will be described in detail below. In order to make the objectives, technical solutions, and advantages of the present application clearer, the present application will be described in further detail below with reference to the accompanying drawings and specific embodiments. It should be understood that the specific embodiments described herein are only to explain the present application and are not limit the present application. For those skilled in the art, the present application may be implemented without some of these specific details. The following description of embodiments is merely intended to provide a better understanding of the present application by illustrating examples thereof.

It is to be noted that the relational terms herein such as first and second are used only to differentiate an entity or operation from another entity or operation, and do not necessarily require or imply any actual relationship or sequence between these entities or operations. Moreover, the terms “include”, “comprise”, and any variation thereof are intended to cover a non-exclusive inclusion. Therefore, a process, method, article, or device that includes a series of elements not only includes such elements, but also includes other elements not specified expressly, or may also include elements inherent to the process, method, article, or device. If no more limitations are made, an element limited by “including . . . ” does not exclude other same elements existing in the process, method, article, or device that includes the element.

It should be understood that when a structure of a component is described, a layer or region being arranged “above” or “on” another layer or region means that the layer or region is directly on another layer or region, or that there is a further layer or region between the layer or region and the another layer or region. Moreover, if the component is flipped, the layer or region will be located “below” or “under” another layer or region.

Embodiments of the present application provide an array substrate, a display panel, and a method for manufacturing an array substrate. Various embodiments of a display panel and a display apparatus will be described below with reference to the accompanying drawings.

The embodiments of the present application provide an array substrate applied to a display panel. The display panel may be an organic light emitting diode (OLED) display panel.

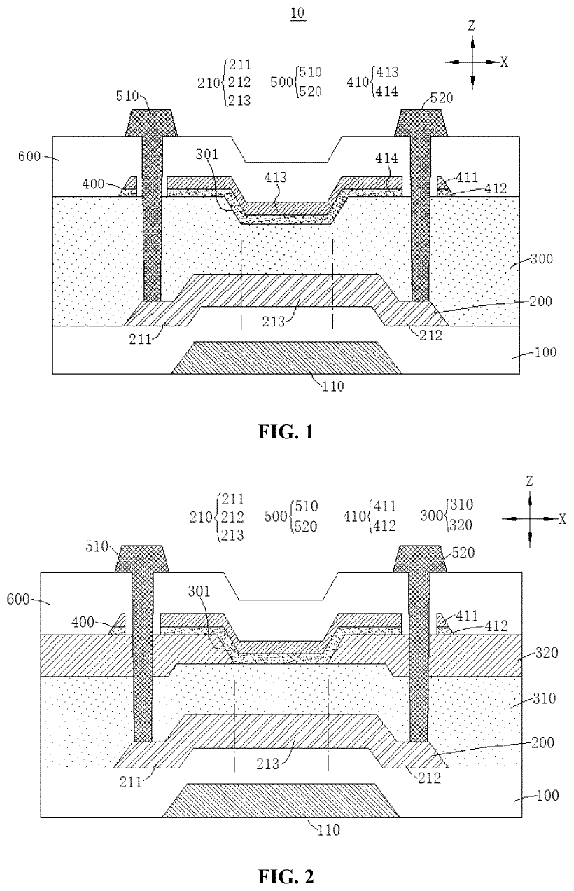

Referring to FIG. 1, FIG. 1 is a partial sectional view of an array substrate 10 according to an embodiment in a first aspect of the present application.

As shown in FIG. 1, in a first aspect of the present application, an embodiment provides an array substrate 10. The array substrate 10 includes a substrate 100, and a first insulating layer 300, a first metal layer 400 and a second insulating layer 600 that are arranged on the substrate 100. The first insulating layer 300 is located on one side of the substrate 100, and the surface of the first insulating layer 300 facing away from the substrate 100 is recessed to form a confining groove 301. The first metal layer 400 is located on the side of the first insulating layer 300 facing away from the substrate 100. The first metal layer 400 includes a signal line 410. The signal line 410 includes a first branch 413 and a second branch 414 surrounding at least part of the first branch 413. The first branch 413 is located in the confining groove 301, and at least part of the second branch 414 is located on the surface of the first insulating layer 300 facing away from the substrate 100. The second insulating layer 600 is located on the side of the first metal layer 400 facing away from the substrate 100. The second insulating layer 600 includes an accommodating groove (not shown) with an opening facing the first metal layer 400. The second branch 414 is located in the accommodating groove.

In the array substrate 10 provided in the embodiments of the present application, the array substrate 10 includes the substrate 100, the first insulating layer 300, the first metal layer 400, and the second insulating layer 600. The first insulating layer 300 is provided with the confining groove 301, and at least part of the signal line 410 is located in the confining groove 301. The signal line 410 includes the first branch 413 located in the confining groove 301 and the second branch 414 located outside the confining groove 301, the accommodating groove of the second insulating layer 600 accommodates the second branch 414, and the second insulating layer 600 may be directly deposited on the first insulating layer 300 and the first metal layer 400, which can simplify manufacturing of the array substrate 10. The confining groove 301 can provide a limit to the signal line 410, thereby determining a position and dimensions of the signal line 410. Therefore, the signal line 410 can be manufactured by using a more mature process such as wet etching, which can simplify manufacturing of the array substrate 10. In addition, when the signal line 410 is required to overlap with another wire, a distance between the first branch 413 in the confining groove 301 and the another wire is relatively short. Therefore, dimensions of an overlapping region between the first branch 413 and the another wire can affect device characteristics. By reasonably arranging the dimensions and the position of the confining groove 301, the characteristics of the device can be controlled, thereby improving the stability of device characteristics. Hence, the array substrate 10 provided in the embodiments of the present application has the advantage of stable device characteristics.

The signal line 410 may be arranged in a variety of manners. For example, the signal line 410 may be located in a frame region, and the signal line 410 includes a scan driving circuit. Alternatively, the signal line 410 is one plate of a capacitor in the array substrate.

In some other embodiments, the array substrate 10 further includes an active layer 200 arranged on the substrate 100. The active layer 200 is located between the substrate 100 and the first insulating layer 300. The active layer 200 includes a semiconductor portion 210. An orthographic projection of the confining groove 301 on the substrate 100 at least partially overlaps with an orthographic projection of the semiconductor portion 210 on the substrate 100. The signal line 410 is a gate line.

In the array substrate 10 provided in the embodiments of the present application, the semiconductor portion 210 and the signal line 410 constitute part of a thin film transistor of a driving circuit of the array substrate 10. A distance between the first branch 413 of the signal line 410 in the confining groove 301 and the semiconductor portion 210 is relatively short. Therefore, an aspect ratio of an overlapping region between the first branch 413 and the semiconductor portion 210 can affect device characteristics of the thin film transistor. By reasonably arranging the dimensions and the position of the confining groove 301, the characteristics of the thin film transistor can be controlled, thereby improving the stability of characteristics of the thin film transistor. Hence, the array substrate 10 provided in the embodiments of the present application has the advantage of stable device characteristics.

The substrate 100 may be arranged in a variety of manners. For example, the substrate 100 is a rigid substrate 100, and the substrate 100 is made of a material including a rigid material such as glass. Alternatively, the substrate 100 is a flexible substrate 100, and the substrate 100 is made of a material including a flexible material such as polyimide. The array substrate 10 may further include a support layer located on the side of the substrate 100 facing away from the active layer 200. The support layer may include a steel layer and/or a foam layer. A layer structure such as a buffer layer may also be provided between the substrate 100 and the active layer 200. Optionally, the substrate 100 may be further provided with a shielding portion 110. The shielding portion 110 is configured to shield light to improve the device characteristics of the thin film transistor affected by light incident on the semiconductor portion 210.

The semiconductor portion 210 of the active layer 200 may be arranged in a variety of manners. For example, the active layer 200 includes a plurality of semiconductor portions 210 distributed at intervals, and the semiconductor portions 210 belong to different thin film transistors respectively. A plurality of confining grooves 301 are also provided. Each confining groove 301 is arranged corresponding to the respective semiconductor portion 210. That is, an orthographic projection of each confining groove 301 on the substrate 100 at least partially overlaps with an orthographic projection of the respective semiconductor portion 210 on the substrate 100. A plurality of signal lines 410 are also provided. The first branch 413 of each signal line 410 is located in the respective confining groove 301.

The confining groove 301 is a groove formed by recessing of the surface of the first insulating layer 300. Therefore, part of the material of the first insulating layer 300 remains between the bottom of the confining groove 301 and the semiconductor portion 210. In other words, the confining groove 301 is not arranged through the first insulating layer 300, and there is an insulating material between a bottom wall surface of the confining groove 301 and the semiconductor portion 210 to prevent a short-circuit connection between the signal line 410 and the semiconductor portion 210.

Optionally, the semiconductor portion 210 includes a source region 211, a channel region 213, and a drain region 212 that are sequentially arranged along a first direction. The orthographic projection of the confining groove 301 on the substrate 100 at least partially overlaps with an orthographic projection of the channel region 213 on the substrate 100. The array substrate 10 further includes a second metal layer 500. The second metal layer 500 includes a source 510 and a drain 520. The source 510 is connected to the source region 211 through a via, and the drain region 212 is connected to the drain 520 through a via.

In such optional embodiments, the source 510, the drain 520, the signal line 410, and the semiconductor portion 210 are combined to form a thin film transistor. A distance between the signal line 410 in the confining groove 301 and the channel region 213 is relatively short. Therefore, an overlapping region between the signal line 410 in the confining groove 301 and the channel region 213 determines device characteristics of the thin film transistor. By reasonably arranging the position and the dimensions of the confining groove 301, the device characteristics of the thin film transistor can be adjusted.

When the array substrate 10 includes the second metal layer 500, the second insulating layer 600 is located between the first metal layer 400 and the second metal layer 500 to prevent a short-circuit connection between the first metal layer 400 and the second metal layer 500. Optionally, another metal layer may also be provided between the first metal layer 400 and the second metal layer 500. “The source 510 is connected to the source region 211 through a via” means that via holes are provided in an insulating material layer (including the first insulating layer 300) between the second metal layer 500 and the semiconductor portion 210, and when the second metal layer 500 is manufactured, a metal material may fall into the via holes and be connected to the semiconductor portion 210, so that the source 510 is connected to the source region 211 through the respective via hole and the drain 520 is connected to the drain region 212 through the respective via hole.

In some embodiments, the array substrate 10 further includes a plurality of wires. For example, the wires of the array substrate 10 include a data line, a scan line, a power line, a voltage reference line, and the like,. The signal line 410 may be connected to the scan line. Optionally, the scan line and the signal line 410 are arranged in a same layer. The signal line 410 may be considered as a partial section on the wire in the first metal layer 400 that overlaps with the channel region 213. The scan line may be a partial section on the signal line in the first metal layer 400 that is misaligned with the channel region 213. One of the source 510 and the drain 520 is connected to the data line. The data line is arranged in a same layer as the source 510 and the drain 520 and is located in the second metal layer 500. The source 510 may be considered as a portion of the signal line in the second metal layer 500 that is connected to the source region 211 through a via, and the drain 520 may be considered as a portion of the signal line in the second metal layer 500 that is connected to the drain region 212 through a via.

Optionally, the orthographic projection of the channel region 213 on the substrate 100 is located within the orthographic projection of the confining groove 301 on the substrate 100. In such embodiments, an overlapping area of the channel region 213 and the signal line 410 in the confining groove 301 can be ensured, thereby ensuring advancement characteristics of the thin film transistor. Optionally, the orthographic projection of the confining groove 301 on the substrate 100 may be an orthographic projection of an opening or the bottom of the confining groove 301 on the substrate 100, or an orthographic projection of any position between the opening and the bottom of the confining groove 301 on the substrate 100.

The first insulating layer 300 may be arranged in a variety of manners. For example, as shown in FIG. 1, the first insulating layer 300 may be provided with a one-layer structure. The first insulating layer 300 is patterned to form the confining groove 301 recessed from the surface of the first insulating layer 300.

In some other embodiments, referring to FIG. 2, FIG. 2 is a partial sectional view of an array substrate 10 according to another embodiment in the first aspect of the present application. As shown in FIG. 2, the first insulating layer 300 includes: a first sub-insulating layer 310 and a second sub-insulating layer 320. The first sub-insulating layer 310 is located on the side of the active layer 200 facing away from the substrate 100. The second sub-insulating layer 320 is located on the side of the first sub-insulating layer 310 facing away from the active layer 200. The confining groove 301 is arranged in the second sub-insulating layer 320.

In such optional embodiments, the first insulating layer 300 includes the first sub- insulating layer 310 and the second sub-insulating layer 320, and the confining groove 301 is arranged in the second sub-insulating layer 320. That is, the confining groove 301 is located above the first sub-insulating layer 310. A distance between the bottom wall surface of the confining groove 301 and the semiconductor portion 210 can be adjusted by controlling a thickness of the first sub-insulating layer 310. In addition, the confining groove 301 is arranged in the second sub-insulating layer 320, so that the confining groove 301 can be obtained only by patterning the second sub-insulating layer 320, and a risk of the confining groove 301 passing through the entire first insulating layer 300 can also be ameliorated.

Optionally, the first sub-insulating layer 310 is arranged over an entire layer. When the array substrate 10 is applied to a display panel, the first sub-insulating layer 310 is continuously provided at least in a display region of the display panel, which can improve insulation performance between the first metal layer 400 and the active layer 200.

Optionally, as shown in FIG. 2, the second sub-insulating layer 320 is arranged over an entire layer. When the array substrate 10 is applied to a display panel, the second sub-insulating layer 320 is continuously provided at least in the display region of the display panel, and the second sub-insulating layer 320 is patterned to form a plurality of confining grooves 301.

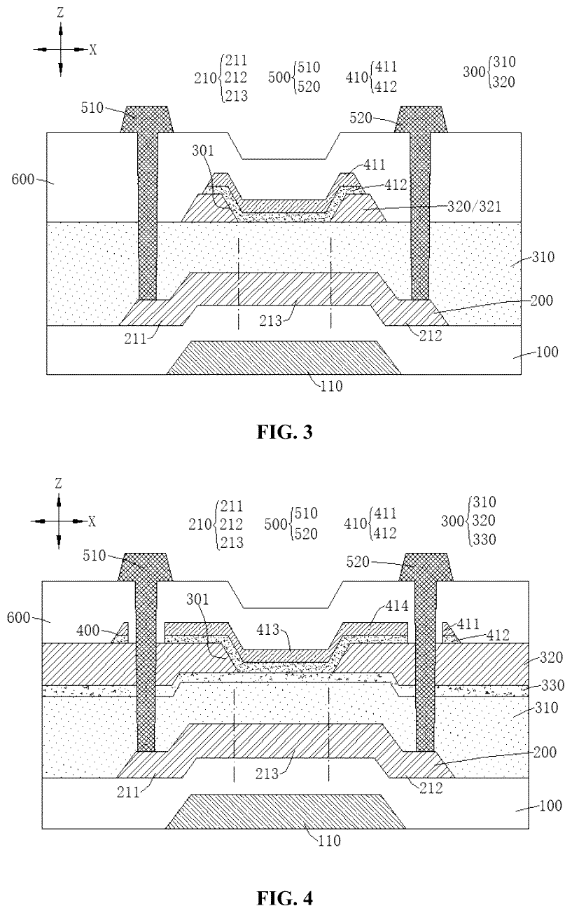

In some other embodiments, referring to FIG. 3, FIG. 3 is a partial sectional view of an array substrate 10 according to still another embodiment in the first aspect of the present application. As shown in FIG. 3, the second sub-insulating layer 320 includes an insulating defining portion 321. The insulating defining portion 321 is located between the source 510 and the drain 520. An orthographic projection of the signal line 410 on the substrate 100 is located within an orthographic projection of the insulating defining portion 321 on the substrate 100.

In such optional embodiments, the second sub-insulating layer 320 includes insulating defining portions 321 independently provided corresponding to the signal line 410 and the confining groove 301, which can reduce thicknesses of film layers between two adjacent insulating defining portions 321, that is, can reduce thicknesses of film layers in regions other than a region where the insulating defining portions 321 are located, making the display panel lighter and thinner.

The first sub-insulating layer 310 is made of a material provided in a variety of manners. For example, the first sub-insulating layer 310 is an inter-gate insulating layer, and the first sub-insulating layer 310 is made of a material including silicon dioxide and the like.

The second sub-insulating layer 320 is made of a material provided in a variety of manners. For example, the second sub-insulating layer 320 is made of a material including at least one of silicon nitride and silicon oxide. Optionally, the second sub-insulating layer 320 may be patterned by photoetching to form the confining groove 301. For example, photoresist may be provided on a surface of the second sub-insulating layer 320, and exposed, developed, and etched to form the confining groove 301.

A thickness of the second sub-insulating layer 320 ranges from 4000 Å to 9000 Å. That is, a depth of the confining groove 301 ranges from 4000 Å to 9000 Å. When the depth of the confining groove 301 is within the above range, an influence on the device characteristics of the thin film transistor caused by overlapping between the signal line 410 outside the confining groove 301 and the channel region 213 due to an excessively short distance between the signal line 410 in the confining groove 301 and the signal line 410 outside the confining groove 301 can be ameliorated, and an influence on conductivity of the signal line 410 caused by possible breakage of the signal line 410 at a side wall of the confining groove 301 due to an excessively long distance between the signal line 410 in the confining groove 301 and the signal line 410 outside the confining groove 301 can also be ameliorated.

Referring to FIG. 4, FIG. 4 is a partial sectional view of an array substrate 10 according to yet another embodiment in the first aspect of the present application.

In some embodiments, as shown in FIG. 4, the first insulating layer 300 further includes an insulating stop layer 330, and the insulating stop layer 330 is located between the first sub-insulating layer 310 and the second sub-insulating layer 320.

In such optional embodiments, through the arrangement of the insulating stop layer 330 between the first sub-insulating layer 310 and the second sub-insulating layer 320, when the second sub-insulating layer 320 is patterned, erroneous etching of the first sub-insulating layer 310 can be ameliorated, and the distance between the bottom wall surface of the confining groove 301 and the semiconductor portion 210 can be ensured.

The insulating stop layer 330 may be shaped in a variety of manners. As shown in FIG. 4, the insulating stop layer 330 may be arranged over an entire layer, which better ameliorates an influence of a corrosive material such as an etching solution on the first sub-insulating layer 310 during the etching of the second sub-insulating layer 320.

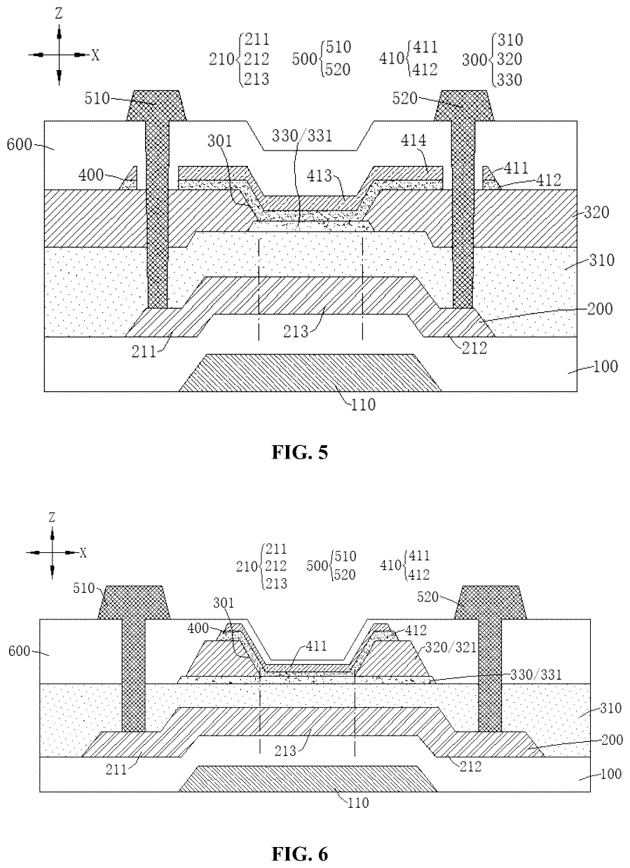

Referring to FIG. 5 and FIG. 6, FIG. 5 is a partial sectional view of an array substrate 10 according to a further embodiment in the first aspect of the present application, and FIG. 6 is a partial sectional view of an array substrate 10 according to a further embodiment in the first aspect of the present application. FIG. 5 and FIG. 6 are different in the arrangement of the second sub-insulating layer 320.

In some other embodiments, as shown in FIG. 5 and FIG. 6, the insulating stop layer 330 may further include an etching stop portion 331. The etching stop portion 331 is located between the source 510 and the drain 520. The orthographic projection of the confining groove 301 on the substrate 100 is located within an orthographic projection of the etching stop portion 331 on the substrate 100.

In such optional embodiments, the confining groove 301 is located in the etching stop portion 331, and the etching stop portion 331 can ameliorate an influence on the first sub-insulating layer 310 caused by formation of the confining groove 301 with etching. Moreover, the corresponding arrangement of the etching stop portion 331 and the confining groove 301 can reduce thicknesses of film layers in regions other than a region where the etching stop portion 331 is located, making the display panel lighter and thinner.

As shown in FIG. 5, when the insulating stop layer 330 is not arranged over the entire layer and includes the etching stop portion 331, the second sub-insulating layer 320 may be arranged over the entire layer, to save materials and reduce thicknesses of regions on the array substrate 10 except the etching stop portion 331. Alternatively, as shown in FIG. 6, when the insulating stop layer 330 is not arranged over the entire layer and includes the etching stop portion 331, the second sub-insulating layer 320 may not be arranged over the entire layer and may include the insulating defining portion 321, to further save the materials and reduce thicknesses of regions on the array substrate 10 except the etching stop portion 331 and the insulating defining portion 321.

The insulating stop layer 330 is made of a material provided in a variety of manners. Optionally, the insulating stop layer 330 is made of a material including at least one of amorphous silicon and silicon oxide, so that when the second sub-insulating layer 320 is etched, an influence of an etching solution on the insulating stop layer 330 can be reduced. Optionally, a thickness of the insulating stop layer 330 ranges from 200 Å to 800 Å. When the thickness of the insulating stop layer 330 is within the above range, erroneous etching of the first sub-insulating layer 310 caused by insufficient protection over the insulating stop layer 330 due to an excessively small thickness of the insulating stop layer 330 can be ameliorated, and an excessive film thickness of the display panel caused by an excessively large thickness of the insulating stop layer 330 can also be ameliorated.

Optionally, during the manufacturing, the insulating stop layer 330 and the second sub-insulating layer 320 are made of different materials or have different material ratios, so that the problem of etching of the insulating stop layer 330 during the etching can be alleviated. Alternatively, material hardness of the insulating stop layer 330 is greater than material hardness of the second sub-insulating layer 320, which alleviates the problem of etching of the insulating stop layer 330.

The signal line 410 may be arranged in a variety of manners. The signal line 410 is, for example, a single-layer metal layer, and at least part of a metal material layer is located in the confining groove 301. For example, the signal line 410 is made of a material including metal materials such as aluminum and aluminum alloy.

In some other embodiments, as shown in FIG. 1 to FIG. 6, the signal line 410 includes a first sub-layer 411 and a second sub-layer 412. The first sub-layer 411 is located on the side of the first insulating layer 300 facing away from the active layer 200. The second sub-layer 412 is located on the side of the first sub-layer 411 facing away from the first insulating layer 300, and the second sub-layer 412 is made of a material including copper.

In such optional embodiments, the signal line 410 includes two structure layers, that is, the signal line 410 includes the first sub-layer 411 and the second sub-layer 412, and the second sub-layer 412 is made of a material including copper. Through the arrangement of the first sub-layer 411, the problem of diffusion of the copper material in the second sub-layer 412 can be alleviated. The copper material has advantages of low impedance and good conductivity, so that the signal line 410 has good conductivity.

In addition, in the array substrate 10 provided in the embodiments of the present application, the first branch 413 is located in the confining groove 301, and an overlapping area of the first branch 413 and the channel region 213 determines device characteristics of the thin film transistor. Therefore, even if the signal line 410 has greater dimensions, the arrangement of the signal line 410 with greater dimensions outside the confining groove 301 may not affect the device characteristics. In other words, in the embodiments of the present application, the dimensions of the signal line 410 may not be limited. When the second sub-layer 412 is made of a material including copper, the second sub-layer 412 may be patterned by wet etching, which can alleviate the problem that the second sub-layer 412 cannot be patterned by wet etching due to an excessively small line width of the signal line 410.

Optionally, when the first metal layer 400 includes a scan line, the scan line and the signal line 410 are arranged in a same layer and made of a copper material. That is, the scan line may also include two structure layers, and the two structure layers of the scan line and the first sub-layer 411 and the second sub-layer 412 of the signal line 410 are arranged in a same layer and made of a same material.

The first sub-layer 411 is made of a material provided in a variety of manners. In order to better prevent the diffusion of the copper material, the first sub-layer 411 may be made of a material including at least one of molybdenum, molybdenum alloy, titanium, and titanium alloy.

In some optional embodiments, a thickness of the first sub-layer 411 may range from 200 Å to 1000 Å.

Optionally, a thickness of the second sub-layer 412 may be greater than or equal to 700 Å. For example, the thickness of the second sub-layer 412 ranges from 700 Å to 4000 Å, so that the second sub-layer 412 has good conductivity.

The source 510 and the drain 520 may be arranged in a variety of manners. As shown in FIG. 1 to FIG. 6, for example, via holes may be provided in the first insulating layer 300 between the second metal layer 500 and the active layer 200. When the source 510 and the drain 520 of the second metal layer 500 are formed, the metal material falls into the via holes so that the source 510 is connected to the source region 211 through the respective via hole and the drain 520 is connected to the drain region 212 through the respective via hole.

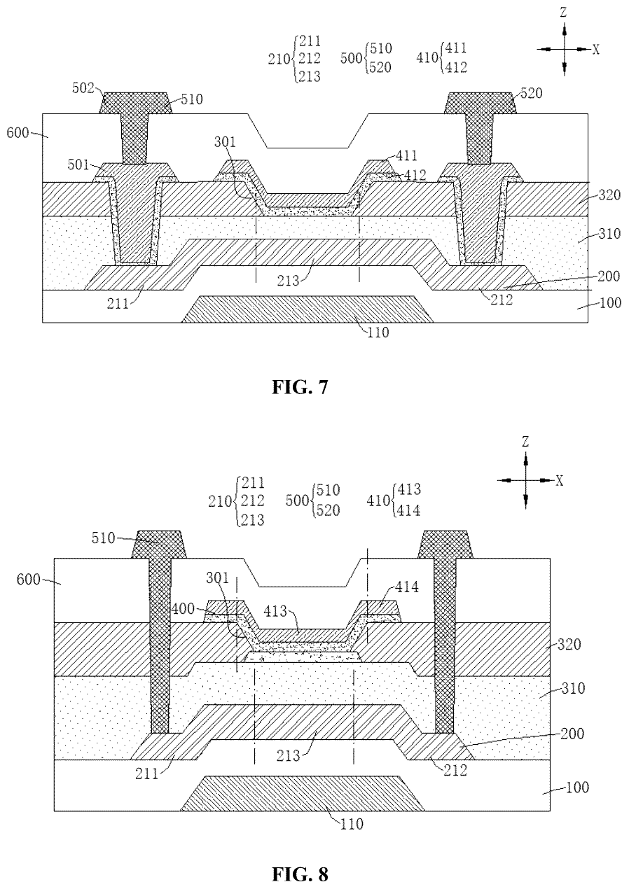

In some other embodiments, the source 510 and the drain 520 may be formed in sections. For example, as shown in FIG. 7, at least one of the source 510 and the drain 520 includes a first sub-section 501 and a second sub-section 502. The first sub-section 501 is located in the first metal layer 400, the first sub-section 501 is connected to the source region 211 and/or the drain region 212 through a via, and the first sub-section 501 is made of a same material as the signal line 410. The second sub-section 502 is located in the second metal layer 500, and the second sub-section 502 is connected to the first sub-section 501 through a via.

In such optional embodiments, the source 510 and/or the drain 520 may include the first sub-section 501 and the second sub-section 502, and manufacturing of the source 510 and/or the drain 520 in sections can ensure the conductivity of the source 510 and/or the drain 520.

Optionally, the source 510 and the drain 520 both include the first sub-section 501 and the second sub-section 502, which can improve the conductivity of both the source 510 and the drain 520 and ensure similar conductivity of the source 510 and the drain 520.

Optionally, when the signal line 410 includes the first sub-layer 411 and the second sub-layer 412, the first sub-section 501 also includes the first sub-layer 411 and the second sub-layer 412, and the first sub-section 501 is made of a material including a copper material, which can improve the conductivity of the first sub-section 501.

The signal line 410 may be shaped in a variety of manners. For example, the signal line 410 is completely located in the confining groove 301.

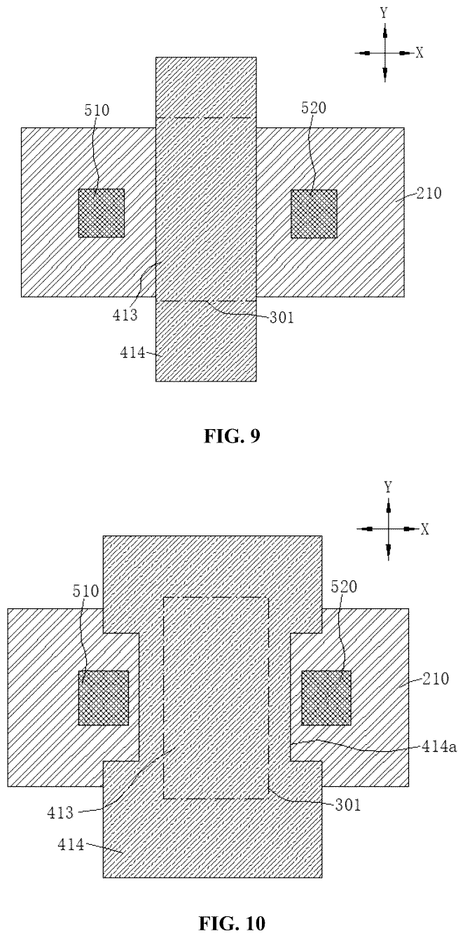

Referring to FIG. 8 and FIG. 9, FIG. 8 is a partial sectional view of an array substrate 10 according to an embodiment in the first aspect of the present application, and FIG. 9 is a top view of a partial layer structure of an array substrate 10 according to an embodiment in the first aspect of the present application. In order to better illustrate the layer structure, FIG. 9 only shows a relative positional relationship among the semiconductor portion 210, the source 510, the drain 520, and the signal line 410.

In some other embodiments, as shown in FIG. 8 and FIG. 9, in some embodiments, an extension dimension of the channel region 213 in a second direction Y is smaller than an extension dimension of the confining groove 301 in the second direction Y. The extension dimension of the confining groove 301 in the second direction Y is greater, which can ensure an overlapping area of the confining groove 301 and the channel region 213 and improve the device characteristics of the thin film transistor.

The second branch 414 may be positioned in a variety of manners. The second branch 414 may be located at any position in a circumferential direction of the first branch 413, as long as the second branch 414 and the first branch 413 are connected to each other.

Optionally, as shown in FIG. 9, at least part of the second branch 414 is located on at least one side of the first branch 413 in the second direction, and the second direction intersects the first direction. Optionally, the second direction may be an extension direction of the scan line, and the second branch 414 is located on the side of the first branch 413 in the second direction, so that the first branch 413 can be connected to the scan line through the second branch 414.

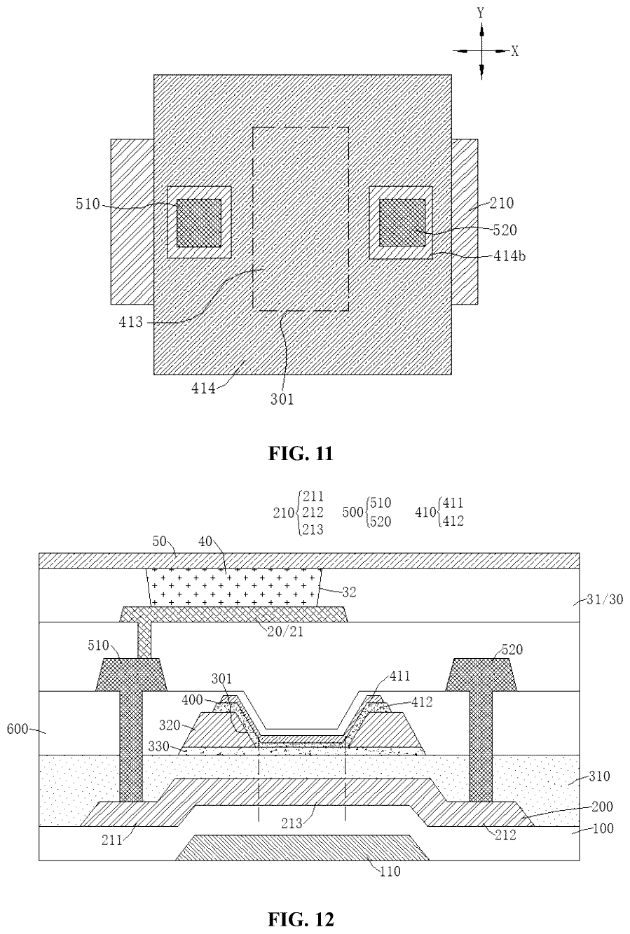

Optionally, as shown in FIG. 10 and FIG. 11, at least part of the second branch 414 is located on at least one side of the first branch 413 in the first direction, and the second branch 414 is insulated from the source 510 and the drain 520. Optionally, the first direction is a width direction of the scan line and the signal line 410, and the second branch 414 is located on at least one side of the first branch 413 in the first direction, which can increase a width of the signal line 410 and increase a distribution area of the signal line 410, thereby reducing resistance of the signal line 410. When the second branch 414 is insulated from the gate and the drain 520, a short-circuit connection of the signal line 410 with the source 510 and the drain 520 can be prevented.

The second branch 414 may be insulated from the source 510 and the drain 520 in a variety of manners. For example, as shown in FIG. 10, the second branch 414 is provided with avoiding grooves 414a. The avoiding grooves 414a pass through the second branch 414 along a thickness direction Z. Edges of the second branch 414 away from the first branch 413 are recessed towards the first branch 413 along the direction X to form the avoiding grooves 414a. Portions of the source 510 and the drain 520 connected to the semiconductor portion 210 through vias are located in the avoiding groove 414a. For example, when through holes are provided in an insulating material layer between the second metal layer 500 and the semiconductor portion 210 so that the source 510 and the drain 520 are connected to the semiconductor portion 210 through the through holes, the through holes are located in the avoiding grooves 414a, so that the source 510 and the drain 520 are insulated from the second branch 414 through the avoiding grooves 414a.

In some other embodiments, as shown in FIG. 11, the second branch 414 may further include avoiding holes 414b. That is, the second branch 414 includes the avoiding holes 414b passing therethrough along the thickness direction Z. The side of each of the avoiding holes 414b facing away from the first branch 413 is further provided with part of the second branch 414, and the portions of the source 510 and the drain 520 connected to the semiconductor portion 210 through vias are located in the avoiding holes 414b, so that the source 510 and the drain 520 are insulated from the second branch 414 through the avoiding holes 414b. For example, when through holes are provided in the insulating material layer between the second metal layer 500 and the semiconductor portion 210 so that the source 510 and the drain 520 are connected to the semiconductor portion 210 through the through holes, the through holes are located in the avoiding holes 414b, so that the source 510 and the drain 520 are insulated from the second branch 414 through the avoiding holes 414b.

In the embodiments of the present application, through the arrangement of the avoiding grooves 414a or the avoiding holes 414b in the second branch 414, it can still be ensured that the source 510 and the drain 520 are insulated from the second branch 414 when there is an interference between positions of the source 510 and/or the drain 520 and the second branch 414 due to a small spacing between the source 510 and the drain 520. As a result, the problem of a short-circuit connection of the source 510 and the drain 520 with the second branch 414 is alleviated, thereby improving a yield of the array substrate 10.

As shown in FIG. 12, in a second aspect of the present application, an embodiment further provides a display panel 1, including the array substrate 10 in any one of the above embodiments in the first aspect. Since the display panel 1 according to the embodiments of the present application includes the array substrate 10 in any one of the above embodiments, the display panel 1 according to the embodiments of the present application achieves the beneficial effects of the array substrate 10 in any one of the above embodiments.

Optionally, the display panel 1 may further include a light-emitting structure layer located on one side of the array substrate 10. A pixel electrode layer 20 may be provided between the light-emitting structure layer and the array substrate 10. The pixel electrode layer 20 includes a plurality of pixel electrodes 21 distributed at intervals. The pixel electrodes 21 may be connected to the sources 510 or the drains 520 of some thin film transistors.

The light-emitting structure layer may include a pixel defining layer 30, and the pixel defining layer 30 includes an isolation portion 31 and a pixel opening 32 defined by the isolation portion 31. The pixel electrode 21 is exposed through the pixel opening 32. A light-emitting unit 40 may be provided in the pixel opening 32. A common electrode layer 50 may be provided on the side of the pixel defining layer 30 facing away from the array substrate 10. The common electrode layer 50 interacts with the pixel electrode 21 and is configured to drive the light-emitting unit 40 to emit light.

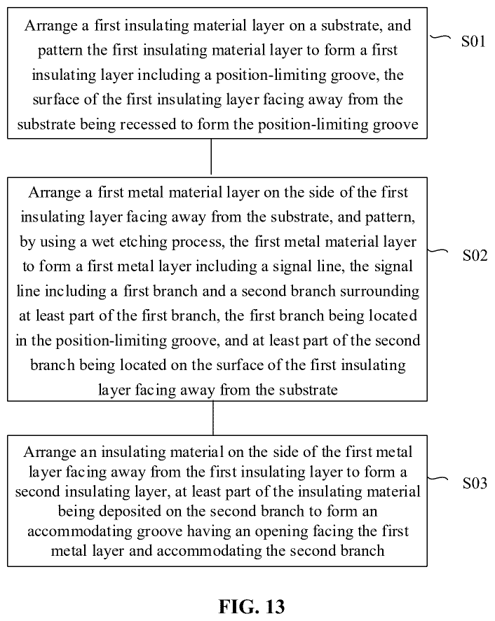

In a third aspect of the present application, an embodiment further provides a method for manufacturing an array substrate 10. The array substrate 10 may be the array substrate 10 in any one of the above embodiments in FIG. 1 to FIG. 11. As shown in FIG. 13, the method for manufacturing the array substrate 10 may include the following steps.

In step S01, a first insulating material layer is arranged on a substrate 100, and the first insulating material layer is patterned to form a first insulating layer 300 including a confining groove 301. The surface of the first insulating layer 300 facing away from the substrate 100 is recessed to form the confining groove 301.

As described above, when the first insulating layer 300 includes a plurality of confining grooves 301 distributed at intervals, an active material layer may be patterned to form the plurality of confining grooves 301.

Optionally, when the array substrate 10 includes an active layer 200, prior to the arrangement of the first insulating material layer in step S01, the active material layer is further arranged on the substrate 100 and the active material layer is patterned to form the active layer 200 including a semiconductor portion 210. Optionally, the active material layer may be patterned by dry etching or wet etching.

In step S02, a first metal material layer is arranged on the side of the first insulating layer 300 facing away from the substrate, and the first metal material layer is patterned by using a wet etching process to form a first metal layer 400 including a signal line 410. The signal line 410 includes a first branch 413 and a second branch 414 surrounding at least part of the first branch 413, the first branch 413 is located in the confining groove 301, and at least part of the second branch 414 is located on the surface of the first insulating layer 300 facing away from the substrate.

In step S03, an insulating material is arranged on the side of the first metal layer 400 facing away from the first insulating layer 300 to form a second insulating layer 600. At least part of the insulating material is deposited on the second branch 414 to form an accommodating groove having an opening facing the first metal layer 400 and accommodating the second branch 414.

In the array substrate 10 manufactured by using the manufacturing method provided in the embodiments of the present application, the array substrate 10 includes the substrate 100, the first insulating layer 300, the first metal layer 400, and the second insulating layer 600. The first insulating layer 300 is provided with the confining groove 301, and at least part of the signal line 410 is located in the confining groove 301. The signal line 410 includes the first branch 413 located in the confining groove 301 and the second branch 414 located outside the confining groove 301, the accommodating groove in the second insulating layer 600 accommodates the second branch 414, and the second insulating layer 600 may be directly deposited on the first insulating layer 300 and the first metal layer 400, which can simplify manufacturing of the array substrate 10. The confining groove 301 can provide a limit to the signal line 410, thereby determining a position and dimensions of the signal line 410. Therefore, the signal line 410 can be manufactured by using a more mature process such as wet etching, which can simplify manufacturing of the array substrate 10. In addition, when the signal line 410 is required to overlap with another wire, a distance between the first branch 413 in the confining groove 301 and the another wire is relatively short. Therefore, dimensions of an overlapping region between the first branch 413 and the another wire can affect device characteristics. By reasonably arranging the dimensions and the position of the confining groove 301, the characteristics of the device can be controlled, thereby improving the stability of device characteristics. Hence, the array substrate 10 provided in the embodiments of the present application has the advantage of stable device characteristics.

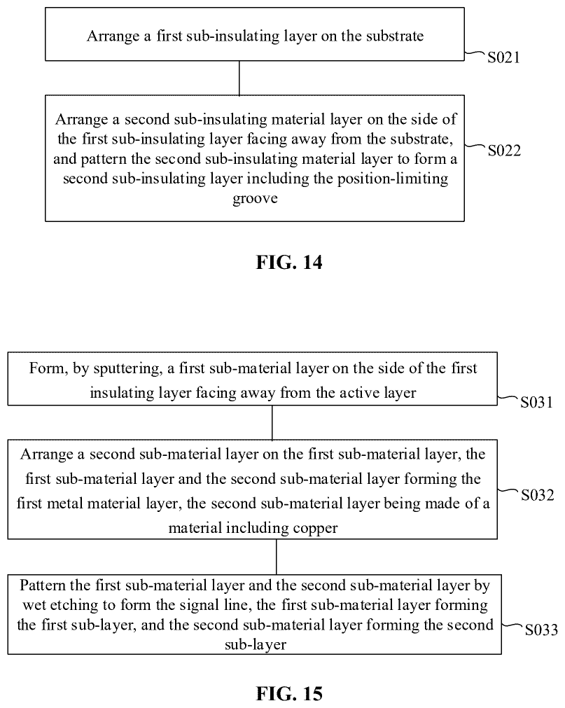

Step S02 may be performed in a variety of manners. Optionally, as shown in FIG. 14, when the first insulating layer 300 includes a first sub-insulating layer 310 and a second sub-insulating layer 320, step S02 includes the following steps.

In step S021, the first sub-insulating layer 310 is arranged on the substrate 100.

In step S022, a second insulating material layer is arranged on the side of the first sub-insulating layer 310 facing away from the active layer 200, and the second insulating material layer is patterned to form a second sub-insulating layer 320 including the confining groove 301.

In such optional embodiments, the first insulating layer 300 includes the first sub- insulating layer 310 and the second sub-insulating layer 320, and the confining groove 301 is arranged in the second sub-insulating layer 320. That is, the confining groove 301 is located above the first sub-insulating layer 310. A distance between the bottom wall surface of the confining groove 301 and the semiconductor portion 210 can be adjusted by controlling a thickness of the first sub-insulating layer 310. In addition, the confining groove 301 is arranged in the second sub-insulating layer 320, so that the confining groove 301 can be obtained only by patterning the second sub-insulating layer 320, and a risk of the confining groove 301 passing through the entire first insulating layer 300 can also be ameliorated.

Optionally, prior to step S022, an insulating stop layer 330 may be further arranged on the side of the first sub-insulating layer 310 facing away from the active layer 200. Optionally, the insulating stop layer 330 may further be patterned to form the above etching stop portion 331.

When the insulating stop layer 330 is arranged on the first sub-insulating layer 310, in step S02, the second insulating material layer is arranged on the side of the insulating stop layer 330 facing away from the active layer 200.

In such optional embodiments, through the arrangement of the insulating stop layer 330 between the first sub-insulating layer 310 and the second sub-insulating layer 320, when the second sub-insulating layer 320 is patterned, erroneous etching of the first sub-insulating layer 310 can be ameliorated, and the distance between the bottom wall surface of the confining groove 301 and the semiconductor portion 210 can be ensured.

Optionally, as described above, the signal line 410 may include a first sub-layer 411 and a second sub-layer 412. The first sub-layer 411 is located on the side of the first insulating layer 300 facing away from the active layer 200. The second sub-layer 412 is located on the side of the first sub-layer 411 facing away from the first insulating layer 300. The second sub-layer 412 is made of a material including copper. Then, as shown in FIG. 15, step S03 may include the following steps.

In step S031, a first sub-material layer is formed by sputtering on the side of the first insulating layer 300 facing away from the active layer 200.

In step S032, a second sub-material layer is arranged on the first sub-material layer, the first sub-material layer and the second sub-material layer form the first metal material layer, and the second sub-material layer is made of a material including copper.

In step S033, the first sub-material layer and the second sub-material layer are patterned by wet etching to form the signal line 410, the first sub-material layer forms the first sub-layer 411, and the second sub-material layer forms the second sub-layer 412.

In such optional embodiments, the signal line 410 includes two structure layers, that is, the signal line 410 includes the first sub-layer 411 and the second sub-layer 412, and the second sub-layer 412 is made of a material including copper. Through the arrangement of the first sub-layer 411, the problem of diffusion of the copper material of the second sub-layer 412 can be alleviated. The copper material has advantages of low impedance and good conductivity, so that the signal line 410 has good conductivity.

In addition, in the array substrate 10 provided in the embodiments of the present application, at least part of the signal line 410 is located in the confining groove 301, and an overlapping area of the signal line 410 in the confining groove 301 and the channel region 213 determines device characteristics of the thin film transistor. Therefore, even if the signal line 410 has greater dimensions, the arrangement of the signal line 410 with greater dimensions outside the confining groove 301 may not affect the device characteristics. In other words, in the embodiments of the present application, the dimensions of the signal line 410 may not be limited. When the second sub-layer 412 is made of a material including copper, the second sub-layer 412 may be patterned by wet etching, which can alleviate the problem that the second sub-layer 412 cannot be patterned by wet etching due to an excessively small line width of the signal line 410.

When the second sub-layer 412 is patterned by wet etching, the copper material can be effectively removed, and the process is more mature. Moreover, due to the existence of the confining groove 301, the copper material may be deposited in the confining groove 301, by changing the position and the dimensions of the confining groove 301, the position and the dimensions of the signal line 410 can be controlled, thereby ameliorating the defect that the wet etching process cannot be applied to an excessively small line width. Compared with dry etching, when the second sub-layer 412 is processed by wet etching, a process device is more mature, and requirement for the thickness of the second sub-layer 412 is lower. Therefore, even if the thickness of the second sub-layer 412 is small, the second sub-layer 412 can be patterned well without generating too much waste and affecting the process yield.

According to the embodiments of the present application as described above, these embodiments are not intended to be exhaustive or to limit the application to the specific embodiments disclosed. Apparently, many modifications and changes may be made according to the above description. The embodiments are chosen and described in the specification in order to better explain the principles and the practical application of the present application, so as to enable those skilled in the art to well utilize the present application and make modifications based on the present application. The present application is to be limited only by the claims and full scope and equivalents thereof.

What is claimed is:

1. An array substrate, comprising:
a substrate;
a first insulating layer located on one side of the substrate, a surface of the first insulating layer facing away from the substrate being recessed to form a confining groove;
a first metal layer located on a side of the first insulating layer facing away from the substrate, the first metal layer comprising a signal line, the signal line comprising a first branch and a second branch surrounding at least part of the first branch, the first branch being located in the confining groove, and at least part of the second branch being located on the surface of the first insulating layer facing away from the substrate; and
a second insulating layer located on a side of the first metal layer facing away from the substrate, the second insulating layer comprising an accommodating groove with an opening facing the first metal layer, and the second branch being located in the accommodating groove.

2. The array substrate of claim 1, further comprising an active layer, the active layer being located between the substrate and the first insulating layer, the active layer comprising a semiconductor portion, an orthographic projection of the confining groove on the substrate at least partially overlapping with an orthographic projection of the semiconductor portion on the substrate, and the signal line being a gate line.

3. The array substrate of claim 2, wherein
the semiconductor portion comprises a source region, a channel region, and a drain region sequentially arranged along a first direction, and the orthographic projection of the confining groove on the substrate at least partially overlaps with an orthographic projection of the channel region on the substrate; and
the array substrate further comprises a second metal layer, the second metal layer is located on a side of the first metal layer facing away from the insulating layer, the second metal layer comprises a source and a drain, the source is connected to the source region through a via, and the drain is connected to the drain region through a via.

4. The array substrate of claim 3, wherein the orthographic projection of the channel region on the substrate is located within the orthographic projection of the confining groove on the substrate; and
an extension dimension of the channel region in a second direction is smaller than an extension dimension of the confining groove in the second direction, and the second direction intersects both of the first direction and a thickness direction of the array substrate.

5. The array substrate of claim 3, wherein the first insulating layer comprises:
a first sub-insulating layer located on a side of the active layer facing away from the substrate; and
a second sub-insulating layer located on a side of the first sub-insulating layer facing away from the active layer, the confining groove being arranged in the second sub-insulating layer.

6. The array substrate of claim 5, wherein the confining groove is arranged through the second sub-insulating layer, the second sub-insulating layer is arranged over an entire layer, or the second sub-insulating layer comprises an insulating defining portion, the insulating defining portion is located between the source and the drain, and an orthographic projection of the signal line on the substrate is located within an orthographic projection of the insulating defining portion on the substrate.

7. The array substrate of claim 5, wherein the first insulating layer further comprises an insulating stop layer, and the insulating stop layer is located between the first sub-insulating layer and the second sub-insulating layer.

8. The array substrate of claim 7, wherein the insulating stop layer is arranged over an entire layer, or the insulating stop layer comprises an etching stop portion, the etching stop portion is located between the source and the drain, and the orthographic projection of the confining groove on the substrate is located within an orthographic projection of the etching stop portion on the substrate.

9. The array substrate of claim 7, wherein the second sub-insulating layer is made of a material comprising at least one of silicon nitride and silicon oxide;
Or, the insulating stop layer is made of a material comprising at least one of amorphous silicon and silicon oxide.

10. The array substrate of claim 7, wherein a thickness of the second sub-insulating layer ranges from 4000 Å to 9000 Å;
Or, a thickness of the insulating stop layer ranges from 200 Å to 800 Å.

11. The array substrate of claim 3, wherein at least one of the source and the drain comprises:
a first sub-section located in the first metal layer, the first sub-section being connected to the source region or the drain region through a via, and the first sub-section being made of a same material as the signal line; and
a second sub-section located in the second metal layer, the second sub-section being connected to the first sub-section through a via.

12. The array substrate of claim 3, wherein
at least part of the second branch is located on at least one side of the first branch in a second direction, and the second direction intersects the first direction.

13. The array substrate of claim 12, wherein at least part of the second branch is located on at least one side of the first branch in the first direction, and the second branch is insulated from the source and the drain.

14. The array substrate of claim 12, wherein the second branch comprises avoiding grooves or avoiding holes, and the second branch is insulated from the source and the drain through the avoiding grooves or the avoiding holes.

15. The array substrate of claim 1, wherein the signal line comprises:
a first sub-layer located on a side of the first insulating layer facing away from the active layer; and
a second sub-layer located on a side of the first sub-layer facing away from the first insulating layer, the second sub-layer being made of a material comprising copper.

16. A display panel, comprising the array substrate of claim 1.

17. A method for manufacturing an array substrate, comprising:
arranging a first insulating material layer on a substrate, patterning the first insulating material layer to form a first insulating layer comprising a confining groove, and a surface of the first insulating layer facing away from the substrate being recessed to form the confining groove;
arranging a first metal material layer on a side of the first insulating layer facing away from the substrate, and patterning, by using a wet etching process, the first metal material layer to form a first metal layer comprising a signal line, the signal line comprising a first branch and a second branch surrounding at least part of the first branch, the first branch being located in the confining groove, and at least part of the second branch being located on the surface of the first insulating layer facing away from the substrate; and
arranging an insulating material on a side of the first metal layer facing away from the first insulating layer to form a second insulating layer, and at least part of the insulating material being deposited on the second branch to form an accommodating groove having an opening facing the first metal layer and accommodating the second branch.

18. The method of claim 17, wherein the arranging a first insulating material layer on a substrate, and patterning the first insulating material layer to form a first insulating layer comprising a confining groove comprises:
arranging a first sub-insulating layer on the substrate; and
arranging a second sub-insulating material layer on a side of the first sub-insulating layer facing away from the substrate, and patterning the second sub-insulating material layer to form a second sub-insulating layer comprising the confining groove.

19. The method of claim 18, wherein prior to the arranging a second sub-insulating material layer on a side of the first sub-insulating layer facing away from the substrate, and patterning the second sub-insulating material layer to form a second sub-insulating layer comprising the confining groove, the method further comprises:
arranging an insulating stop layer on the side of the first sub-insulating layer facing away from the substrate;
wherein the arranging a second sub-insulating material layer on the side of the first sub- insulating layer facing away from the substrate, and patterning the second sub-insulating material layer to form a second sub-insulating layer comprising the confining groove comprises: arranging the second sub-insulating material layer on a side of the insulating stop layer facing away from the substrate.

20. The method of claim 17, wherein the signal line comprises a first sub-layer and a second sub-layer, the first sub-layer is located on the side of the first insulating layer facing away from the substrate, the second sub-layer is located on a side of the first sub-layer facing away from the first insulating layer, and the second sub-layer is made of a material comprising copper, and
wherein the arranging a first metal material layer on a side of the first insulating layer facing away from the substrate, and patterning the first metal material layer to form a first metal layer comprising a signal line comprises:
forming, by sputtering, a first sub-material layer on the side of the first insulating layer facing away from the substrate;
arranging a second sub-material layer on the first sub-material layer, the first sub-material layer and the second sub-material layer forming the first metal material layer, and the second sub-material layer being made of a material comprising copper; and
patterning the first sub-material layer and the second sub-material layer by wet etching to form the signal line, the first sub-material layer forming the first sub-layer, and the second sub-material layer forming the second sub-layer.
